(19) United States
(12) Patent Application Publication
(10) Pub. No.: US 2019/0206748 A1
(43) Pub. Date: Jul. 4, 2019

(54) Semiconductor Device and Method for Detecting a Crack of the Semiconductor Device

(71) Applicant: Sanken Electric Co., Ltd., Saitama (JP)

(72) Inventors: Hiroshi SHIKAUCHI, Saitama (JP); Tomonori HOTATE, Saitama (JP); Yuki TANAKA, Saitama (JP); Shinji KUDOH, Saitama (JP)

(73) Assignee: Sanken Electric Co., Ltd., Saitama (JP)

(21) Appl. No.: 15/856,148

(22) Filed: Dec. 28, 2017

(51) Int. Cl. H01L 21/66; H01L 23/00; H01L 29/872; H01L 29/66; G01N 27/20

(52) U.S. Cl. CPC H01L 22/34; H01L 23/562; H01L 29/1608; H01L 29/66143; G01N 27/20; H01L 29/872

(57) ABSTRACT

A semiconductor device and a method for detecting a crack of the semiconductor device are provided. The semiconductor device includes a crack sensor having a SBD structure; the SBD structure at least is configured on a first side of a semiconductor body and configured to detect a crack on the first side of the semiconductor body. Therefore, a crack on the surface of the semiconductor device can be detected by the crack sensor with high precision and simple structure.

### TECHNICAL FIELD

Embodiments of the present disclosure generally relate to the field of semiconductors, and more particularly, to a semiconductor device and a method for detecting a crack of the semiconductor device.

### BACKGROUND

A semiconductor device (or may be referred to as a semiconductor element, component, apparatus, and so on) may include a semiconductor body and one or more electrodes. For example, materials mainly used in the semiconductor body may be silicon carbide (SiC). Furthermore, some regions may be configured within the semiconductor body.

The semiconductor device may be, for instance, a diode or a transistor such as an IGFET (Insulated Gate Field Effect Transistor), a MOSFET (Metal Oxide Semiconductor Field Effect Transistor) or an IGBT (Insulated Gate Bipolar Transistor), and so on.

In general, during a production and/or an operation of the semiconductor device, one or more cracks may occur and propagate in/on the semiconductor body. Due to such a crack, a semiconductor device may be defective as soon as the crack occurs, or become defective over the course of time as the crack propagates in/on the semiconductor body. Hence, there is a need for detecting a crack of the semiconductor device.

FIG. 1 is a diagram which shows an example of a semiconductor device in the prior art. As shown in FIG. 1, a semiconductor device may include a semiconductor body 1 and a crack sensor 5. The semiconductor body 1 may at least includes a top side 11 and a bottom side 12.

As shown in FIG. 1, the crack sensor 5 extends into the semiconductor body 1 such that a distance d2 between the crack sensor 5 and the bottom side 12 is less than a thickness d1 of the semiconductor body 1. Furthermore, the crack sensor 5 includes a pn-junction 57. Thus, evaluating a leakage current of the pn-junction 57 or evaluating a change of the leakage current of the pn-junction 57, allows for detecting an occurrence of a crack within the semiconductor body 1.

Therefore, the crack sensor 5 can detect cracks that occur inside the semiconductor body 1 distant from the top side 11. The smaller the distance d2 is, the higher the probability for the crack sensor 5 to detect a crack is.

Reference document 1: US2016/0254200A1.

This section introduces aspects that may facilitate a better understanding of the disclosure. Accordingly, the statements of this section are to be read in this light and are not to be understood as admissions about what is in the prior art or what is not in the prior art.

### SUMMARY

However, the inventor found that it is difficult to detect a crack on the surface of the semiconductor device in the existing technology; in addition, for the crack sensor (such as including a pn-junction) in the existing technology, a region occupied by it may be large and a structure of it may be complex. Hence, there is a need for detecting a crack on the surface of the semiconductor device by a crack sensor with high precision and simple structure.

In order to solve at least part of the above problems, methods, apparatus, devices are provided in the present disclosure. Features and advantages of embodiments of the present disclosure will also be understood from the following description of specific embodiments when read in conjunction with the accompanying drawings, which illustrate, by way of example, the principles of embodiments of the present disclosure.

In general, embodiments of the present disclosure provide a semiconductor device and a method for detecting a crack of the semiconductor device. It is expected to detect a crack on the surface of the semiconductor device by a crack sensor with high precision and simple structure in this disclosure.

In a first aspect, a semiconductor device is provided. The semiconductor device includes: a semiconductor body having a first side and a second side; and a crack sensor having a SBD (Schottky Barrier Diode) structure; the SBD structure at least is configured on the first side of the semiconductor body and configured to detect a crack on the first side of the semiconductor body.

In one embodiment, the SBD structure is further configured in the semiconductor body and configured to detect a crack in the semiconductor body.

In one embodiment, the SBD structure is extended into the semiconductor body and a distance between the crack sensor and the second side of the semiconductor body is less than a thickness of the semiconductor body.

In one embodiment, the crack sensor is partially arranged in a trench formed in the semiconductor body.

In one embodiment, the crack sensor is configured to determine that a crack exists on/in the semiconductor body when a current and/or a resistance of the SBD structure differ from a specified value by more than a pre-defined difference.

In one embodiment, the semiconductor device further includes: a crack sensor electrode pad and/or a dielectric layer configured on the first side of the semiconductor body.

In one embodiment, the semiconductor device further includes: a crack sensor having a pn-junction; the crack sensor having the pn-junction is configured within the semiconductor body.

In one embodiment, the crack sensor having the pn-junction is arranged at an inner side than the crack sensor having the SBD structure.

In a second aspect, a method for detecting a crack of a semiconductor device is provided the semiconductor device includes a semiconductor body having a first side and a second side; the semiconductor device further includes a crack sensor having a SBD structure which at least is configured on the first side of the semiconductor body;

the method includes: specifying a first value of a characteristic variable of the crack sensor; determining a second value of the characteristic variable of the crack sensor at a different time than the first value is specified; and determining that the semiconductor body has a crack when the second value differs from the first value by more than a pre-defined difference.

In one embodiment, the characteristic variable is a current and/or a resistance of the SBD structure.

In a third aspect, a method for forming a semiconductor device is provided. The method includes: providing a semiconductor body which has a first side and a second side; and providing a crack sensor which has a SBD structure; the SBD structure at least is configured on the first side of the semiconductor body and configured to detect a crack on the first side of the semiconductor body.

In one embodiment, the SBD structure is further configured in the semiconductor body and configured to detect a crack in the semiconductor body.

According to various embodiments of the present disclosure, a crack sensor having a SBD structure is provided; the SBD structure at least is configured on a first side of a semiconductor body and configured to detect a crack on the first side of the semiconductor body. Therefore, a crack on the surface of the semiconductor device can be detected by the crack sensor with high precision and simple structure.

### BRIEF DESCRIPTION OF THE DRAWINGS

The above and other aspects, features, and benefits of various embodiments of the disclosure will become more fully apparent, by way of example, from the following detailed description with reference to the accompanying drawings, in which like reference numerals or letters are used to designate like or equivalent elements. The drawings are illustrated for facilitating better understanding of the embodiments of the disclosure and not necessarily drawn to scale, in which:

FIG. 1 is a diagram which shows an example of a semiconductor device in the prior art;

FIG. 2 is a diagram which shows a schematic illustration of a cross-section of a semiconductor device 200 in accordance with an embodiment of the present disclosure;

FIG. 3 is a diagram which shows a schematic illustration of a cross-section of a semiconductor device 300 in accordance with an embodiment of the present disclosure;

FIG. 4 is a diagram which shows a schematic illustration of a cross-section of a semiconductor device 400 in accordance with an embodiment of the present disclosure;

FIG. 5 is a top view of a semiconductor device 500 having a crack sensor in accordance with an embodiment of the present disclosure;

FIG. 6 is a vertical cross- sectional view through a section of the semiconductor device 500 of FIG. 5 in cross-sectional plane El-El;

FIG. 7 is a diagram which shows a method 700 for detecting a crack of a semiconductor device in accordance with an embodiment of the present disclosure.

FIG. 8 is a diagram which shows a method 800 for forming a semiconductor device in accordance with an embodiment of the present disclosure.

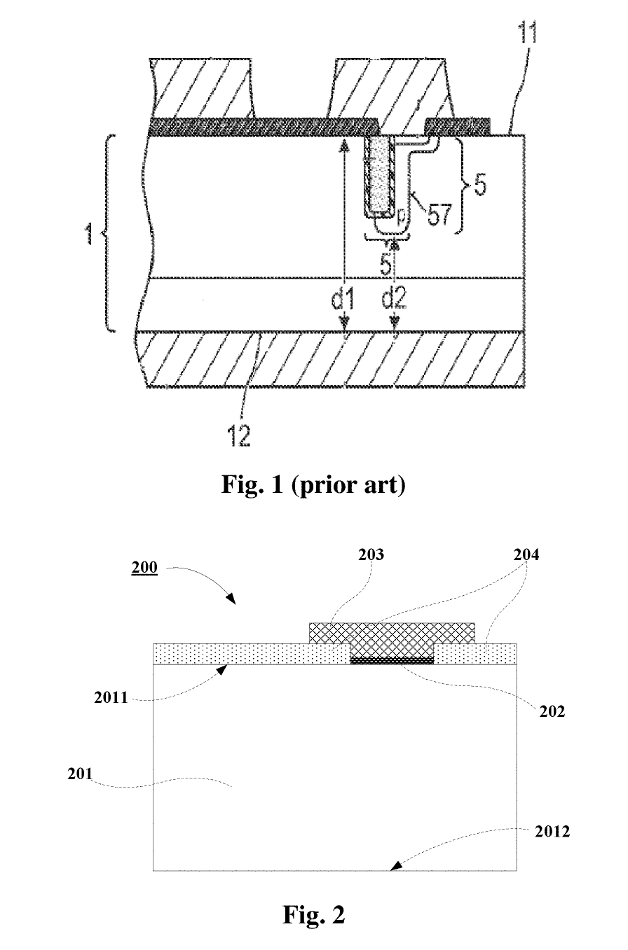

### DETAILED DESCRIPTION

The present disclosure will now be described with reference to several example embodiments. It should be understood that these embodiments are discussed only for the purpose of enabling those skilled persons in the art to better understand and thus implement the present disclosure, rather than suggesting any limitations on the scope of the present disclosure.

It should be understood that when an element is referred to as being “connected” or “coupled” or “contacted” to another element, it may be directly connected or coupled or contacted to the other element or intervening elements may be present. In contrast, when an element is referred to as being “directly connected” or “directly coupled” or “directly contacted” to another element, there are no intervening elements present. Other words used to describe the relationship between elements should be interpreted in a like fashion (e.g., “between” versus “directly between”, “adjacent” versus “directly adjacent”, etc.).

As used herein, the terms “first” and “second” refer to different elements. The singular forms “a” and “an” are intended to include the plural forms as well, unless the context clearly indicates otherwise. The terms “comprises,” “comprising,” “has,” “having,” “includes” and/or “including” as used herein, specify the presence of stated features, elements, and/or components and the like, but do not preclude the presence or addition of one or more other features, elements, components and/or combinations thereof.

The term “based on” is to be read as “based at least in part on”. The term “cover” is to be read as “at least in part cover”. The term “one embodiment” and “an embodiment” are to be read as “at least one embodiment”. The term “another embodiment” is to be read as “at least one other embodiment”. Other definitions, explicit and implicit, may be included below.

In this disclosure, unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

### A First Aspect of Embodiments

A semiconductor device is provided in those embodiments.

FIG. 2 is a diagram which shows a schematic illustration of a cross-section of a semiconductor device 200 in accordance with an embodiment of the present disclosure. As shown in FIG. 2, the semiconductor device 200 includes a semiconductor body 201 and a crack sensor 202.

As shown in FIG. 2, the semiconductor body 201 at least includes a first side (such as a top side) 2011 and a second side (such as a bottom side) 2012; and the crack sensor 202 includes a SBD (Schottky Barrier Diode) structure; the SBD structure at least is configured on the first side 2011 of the semiconductor body 201 and configured to detect a crack on the first side 2011 of the semiconductor body 201.

For example, the SBD structure may be configured by using one or more of the Schottky metal, such as gold, silver, aluminum and platinum, and so on. However, it is not limited thereto in this disclosure, any SBD structure in the relevant art may be adopted.

As shown in FIG. 2, the semiconductor device 200 may further include a crack sensor electrode pad 203 and a dielectric layer 204. However, it is not limited thereto in this disclosure, other components or elements of the semiconductor device are omitted for the sake of simplicity.

It should be appreciated that silicon or another material may be mainly used in the semiconductor device. However, it is not limited thereto, for example, semiconductor materials with a larger band gap may also be used. In this disclosure, silicon carbide may be used as an example of a material of the semiconductor device.

In an embodiment, the crack sensor 202 may be configured to determine that a crack exists on/in the semiconductor body when a current and/or a resistance of the SBD structure differ from a specified value by more than a pre-defined difference.

For example, a first value of a current of the SBD structure may be specified at a first point of time, and a second value of a current of the SBD structure may be determined at a second point of time by interrupting a connection line. Then the first value and the second value are compared; and it may be determined that the semiconductor body has a crack when the second value differs from the first value by more than a pre-defined difference.

It should be appreciated that the above determining method is only an example, but it is not limited thereto. For the detail of determining the crack based on the current and/or the resistance, the relevant art could be referred.

In this disclosure, a region occupied by the SBD structure could be small and a structure of the SBD could be simple; in addition, the detection accuracy could be high. Therefore, a crack on the surface of the semiconductor device can be detected by the crack sensor with high precision and simple structure.

In an embodiment, the SBD structure may be further configured in the semiconductor body and configured to detect a crack in the semiconductor body.

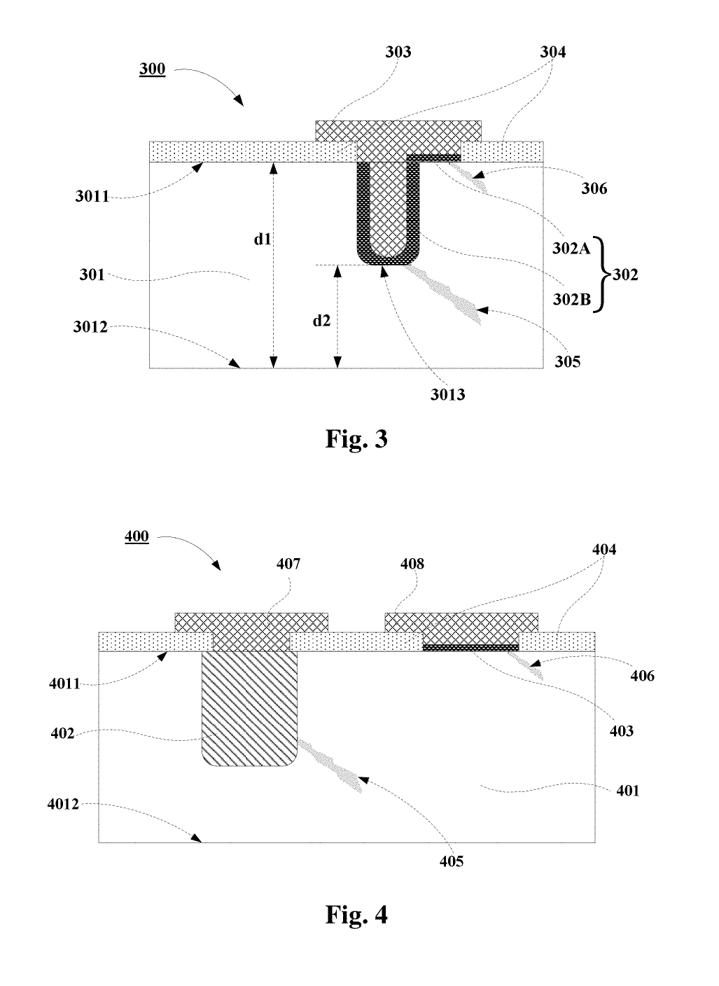

FIG. 3 is a diagram which shows a schematic illustration of a cross-section of a semiconductor device 300 in accordance with an embodiment of the present disclosure. As shown in FIG. 3, the semiconductor device 300 includes a semiconductor body 301 and a crack sensor 302.

As shown in FIG. 3, the semiconductor body 301 at least includes a first side (such as a top side) 3011 and a second side (such as a bottom side) 3012; the semiconductor device 300 may further include a crack sensor electrode pad 303 and a dielectric layer 304.

As shown in FIG. 3, the crack sensor 302 includes a SBD structure; and the SBD structure includes a first portion 302A and a second portion 302B. The first portion 302A of the SBD structure is configured on the first side 3011 of the semiconductor body 301 and configured to detect a crack on the first side 3011 of the semiconductor body 301. The second portion 302B of the SBD structure is configured within the semiconductor body 301 and configured to detect a crack within the semiconductor body 301.

As shown in FIG. 3, the crack sensor 302 is partially arranged in a trench (or groove) 3013 formed in the semiconductor body 301. That is to say, the SBD structure is extended into the semiconductor body 301 and a distance d2 between the crack sensor 302 and the second side 3012 of the semiconductor body 301 is less than a thickness dl of the semiconductor body 301.

As shown in FIG. 3, for example, a crack 305 within the semiconductor body 301 could be detected by the second portion 302B of the SBD structure while a crack 306 on the semiconductor body 301 could be detected by the first portion 302A of the SBD structure.

Therefore, both of a crack on the surface of the semiconductor device and a crack inside the semiconductor device can be detected by the crack sensor with high precision and simple structure.

In an embodiment, the SBD structure may be combined with a crack sensor having a pn-junction to detect a crack in/on the semiconductor body.

FIG. 4 is a diagram which shows a schematic illustration of a cross-section of a semiconductor device 400 in accordance with an embodiment of the present disclosure. As shown in FIG. 4, the semiconductor device 400 includes a semiconductor body 401, a first crack sensor 402 having a pn-junction and a second crack sensor 403 having a SBD structure.

As shown in FIG. 4, the semiconductor body 401 at least includes a first side (such as a top side) 4011 and a second side (such as a bottom side) 4012; the semiconductor device 400 may further include a first crack sensor electrode pad 407, a second crack sensor electrode pad 408 and a dielectric layer 404. The first crack sensor 402 is configured within the semiconductor body 401 and the second crack sensor 403 is configured on the semiconductor body 401. The first crack sensor 402 is arranged at the inner side than the second crack sensor 403.

As shown in FIG. 4, for example, a crack 405 within the semiconductor body 401 could be detected by the first crack sensor 402 while a crack 406 on the semiconductor body 401 could be detected by the second crack sensor 403.

Therefore, both of a crack on the surface of the semiconductor device and a crack inside the semiconductor device can be detected by the crack sensor combined with the SBD structure and the pn-junction.

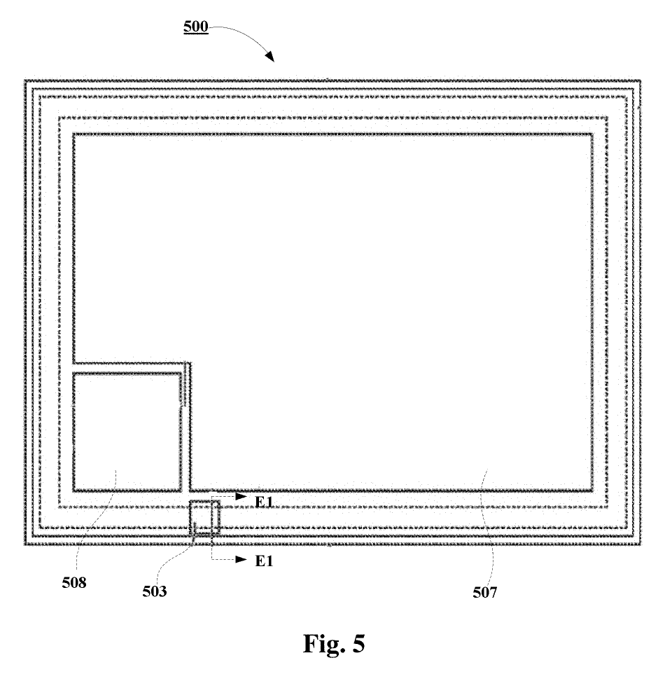

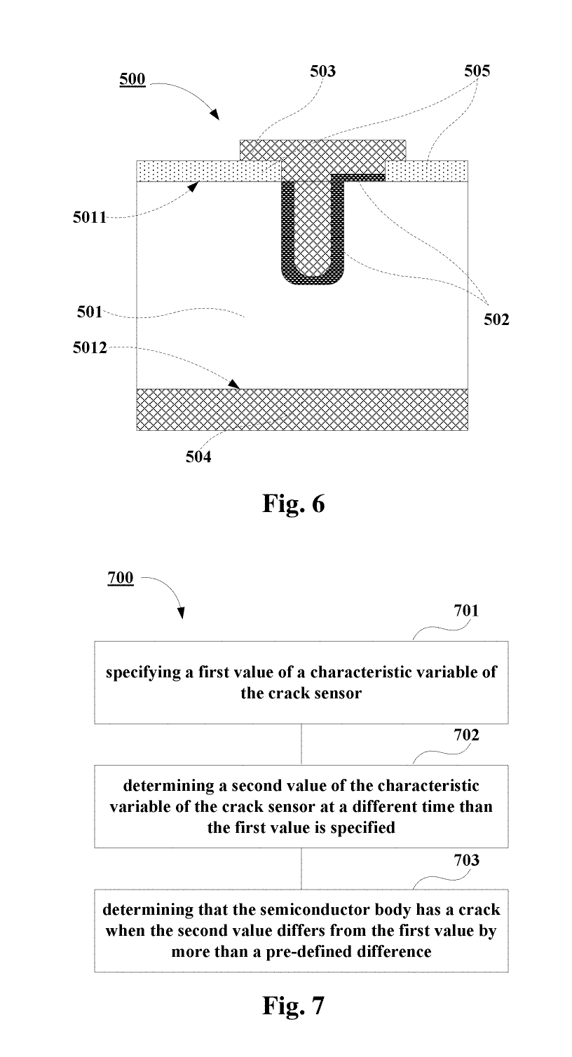

FIG. 5 is a top view of a semiconductor device 500 having a crack sensor in accordance with an embodiment of the present disclosure. FIG. 6 is a vertical cross-sectional view through a section of the semiconductor device 500 of FIG. 5 in cross-sectional plane E1-E1. As shown in FIG. 5, the semiconductor device 500 is exemplarily illustrated as a transistor.

As shown in FIG. 5 and FIG. 6, a semiconductor device 500 includes a semiconductor body 501 and a crack sensor 502 having a SBD structure. A part of the crack sensor 502 is configured on the semiconductor body 501 and other part of the crack sensor 502 is extended into the semiconductor body 501.

As shown in FIG. 5 and FIG. 6, the semiconductor device 500 may further include a first electrode (such as a source electrode) 507, a second electrode (such as a drain electrode) 504, a third electrode (such as a gate electrode) 508, a crack sensor electrode pad 503 and a dielectric layer 505. The first electrode 507, the third electrode 508, the crack sensor electrode pad 503 are configured on a top side 5011 of the semiconductor body 501; and the second electrode 504 is configured under a bottom side 5012 of the semiconductor body 501. As shown in FIG. 5, the crack sensor electrode pad 503 is configured around the outer edge of the semiconductor device 500.

For another example, in case that the crack sensor electrode pad 503 applies to a diode, the third electrode 508 can be omitted. The first electrode 507 and the second electrode 504 can be an anode electrode and a cathode electrode each.

It is to be understood that, the above examples or embodiments are discussed for illustration, rather than limitation. Those skilled in the art would appreciate that there may be many other embodiments or examples within the scope of the present disclosure.

As can be seen from the above embodiments, a crack sensor having a SBD structure is provided; the SBD structure at least is configured on a first side of a semiconductor body and configured to detect a crack on the first side of the semiconductor body. Therefore, a crack on the surface of the semiconductor device can be detected by the crack sensor with high precision and simple structure.

In addition, the SBD structure may be further configured in the semiconductor body and configured to detect a crack in the semiconductor body. Therefore, both of a crack on the surface of the semiconductor device and a crack inside the semiconductor device can be detected by the crack sensor with high precision and simple structure.

### A Second Aspect of Embodiments

A method for detecting a crack of a semiconductor device is provided in these embodiments. The semiconductor device is illustrated in the first aspect of embodiments, and the same contents as those in the first aspect of embodiments are omitted.

FIG. 7 is a diagram which shows a method for detecting a crack of a semiconductor device in accordance with an embodiment of the present disclosure. As shown in FIG. 7, the method 700 includes:

Block 701, specifying a first value of a characteristic variable of the crack sensor;

Block 702, determining a second value of the characteristic variable of the crack sensor at a different time than the first value is specified; and

Block 703, determining that the semiconductor body has a crack when the second value differs from the first value by more than a pre-defined difference.

In an embodiment, the characteristic variable may be a current and/or a resistance of the SBD structure; and it is not limited thereto.

It should be appreciated that FIG. 7 is only an example of the disclosure, but it is not limited thereto. For example, the order of operations at blocks may be adjusted, and/or, some blocks or steps may be omitted. Moreover, some blocks or steps not shown in FIG. 7 may be added.

As can be seen from the above embodiments, the SBD structure at least is configured on a first side of a semiconductor body and configured to detect a crack on the first side of the semiconductor body. Therefore, a crack on the surface of the semiconductor device can be detected by the crack sensor with high precision and simple structure.

### A Third Aspect of Embodiments

A method for forming a semiconductor device is provided in these embodiments. The semiconductor device is illustrated in the first aspect of embodiments, and the same contents as those in the first aspect of embodiments are omitted.

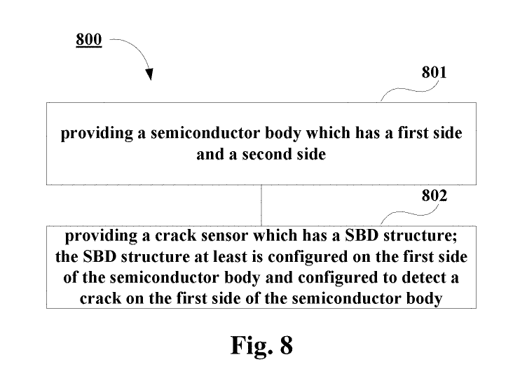

FIG. 8 is a diagram which shows a method for forming a semiconductor device in accordance with an embodiment of the present disclosure. As shown in FIG. 8, the method 800 includes:

Block 801, providing a semiconductor body which has a first side and a second side; and

Block 802, providing a crack sensor which has a SBD structure; the SBD structure at least is configured on the first side of the semiconductor body and configured to detect a crack on the first side of the semiconductor body.

In an embodiment, the SBD structure is further configured in the semiconductor body and configured to detect a crack in the semiconductor body.

It should be appreciated that FIG. 8 is only an example of the disclosure, but it is not limited thereto. For example, the order of operations at blocks may be adjusted, and/or, some blocks or steps may be omitted. Moreover, some blocks or steps not shown in FIG. 8 may be added.

As can be seen from the above embodiments, a crack sensor having a SBD structure is provided; the SBD structure at least is configured on a first side of a semiconductor body and configured to detect a crack on the first side of the semiconductor body. Therefore, a crack on the surface of the semiconductor device can be detected by the crack sensor with high precision and simple structure.

In addition, the SBD structure may be further configured in the semiconductor body and configured to detect a crack in the semiconductor body. Therefore, both of a crack on the surface of the semiconductor device and a crack inside the semiconductor device can be detected by the crack sensor with high precision and simple structure.

Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and integrated circuits (ICs) with minimal experimentation.

Generally, various embodiments of the present disclosure may be implemented in hardware or special purpose circuits, software, logic or any combination thereof. Some aspects may be implemented in hardware, while other aspects may be implemented in firmware or software which may be executed by a controller, microprocessor or other computing device.

While various aspects of embodiments of the present disclosure are illustrated and described as block diagrams, flowcharts, or using some other pictorial representation, it will be appreciated that the blocks, apparatus, systems, techniques or methods described herein may be implemented in, as non-limiting examples, hardware, software, firmware, special purpose circuits or logic, general purpose hardware or controller or other computing devices, or some combination thereof.

Further, while operations are depicted in a particular order, this should not be understood as requiring that such operations be performed in the particular order shown or in sequential order, or that all illustrated operations be performed, to achieve desirable results. In certain circumstances, multitasking and parallel processing may be advantageous.

Likewise, while several specific implementation details are contained in the above discussions, these should not be construed as limitations on the scope of the present disclosure, but rather as descriptions of features that may be specific to particular embodiments. Certain features that are described in the context of separate embodiments may also be implemented in combination in a single embodiment. Conversely, various features that are described in the context of a single embodiment may also be implemented in multiple embodiments separately or in any suitable sub-combination.

Although the present disclosure has been described in language specific to structural features and/or methodological acts, it is to be understood that the present disclosure defined in the appended claims is not necessarily limited to the specific features or acts described above. Rather, the specific features and acts described above are disclosed as example forms of implementing the claims.

What is claimed is:

1. A semiconductor device, comprising:
a semiconductor body having a first side and a second side; and
a crack sensor having a SBD (Schottky Barrier Diode) structure, wherein the SBD structure at least is configured on the first side of the semiconductor body and configured to detect a crack on the first side of the semiconductor body.

2. The semiconductor device according to the claim 1, wherein the SBD structure is further configured in the semiconductor body and configured to detect a crack in the semiconductor body.

3. The semiconductor device according to the claim 2, wherein the SBD structure is extended into the semiconductor body and a distance between the crack sensor and the second side of the semiconductor body is less than a thickness of the semiconductor body.

4. The semiconductor device according to the claim 2, wherein the crack sensor is partially arranged in a trench formed in the semiconductor body.

5. The semiconductor device according to the claim 1, wherein the crack sensor is configured to determine that a crack exists on/in the semiconductor body when a current and/or a resistance of the SBD structure differ from a specified value by more than a pre-defined difference.

6. The semiconductor device according to the claim 1, wherein the semiconductor device further comprises:
a crack sensor electrode pad and/or a dielectric layer configured on the first side of the semiconductor body.

7. The semiconductor device according to the claim 1, wherein the semiconductor device further comprises:
a crack sensor having a pn-junction; wherein the crack sensor having the pn-junction is configured within the semiconductor body.

8. The semiconductor device according to the claim 7, wherein the crack sensor having the pn-junction is arranged at an inner side than the crack sensor having the SBD structure.

9. A method for detecting a crack of a semiconductor device, wherein the semiconductor device comprises a semiconductor body having a first side and a second side; the semiconductor device further comprises a crack sensor having a SBD (Schottky Barrier Diode) structure which at least is configured on the first side of the semiconductor body; comprising:
specifying a first value of a characteristic variable of the crack sensor;
determining a second value of the characteristic variable of the crack sensor at a different time than the first value is specified; and
determining that the semiconductor body has a crack when the second value differs from the first value by more than a pre-defined difference.

10. The method according to the claim 9, wherein the characteristic variable is a current and/or a resistance of the SBD structure.

11. A method for forming a semiconductor device, comprising:
providing a semiconductor body which has a first side and a second side; and
providing a crack sensor which has a SBD (Schottky Barrier Diode) structure, wherein the SBD structure at least is configured on the first side of the semiconductor body and configured to detect a crack on the first side of the semiconductor body.

12. The method according to the claim 11, wherein the SBD structure is further configured in the semiconductor body and configured to detect a crack in the semiconductor body.
